(19) United States
(12) Patent Application Publication
(10) Pub. No.: US 2017/0267532 A1
(43) Pub. Date: Sep. 21, 2017

(54) MULTI-FUNCTIONALIZED CARBON NANOTUBES

(71) Applicant: SHT SMART HIGH-TECH AB, Göteborg (SE)

(72) Inventor: Johan LIU, VÄSTRA FRÖLUNDA (SE)

(21) Appl. No.: 15/531,502

(22) PCT Filed: Dec. 22, 2014
(86) PCT No.: PCT/EP2014/079045

§ 371 Date: May 30, 2017

(51) Int. Cl. C01B 31/04; C08K 7/06; C08K 3/04; H05K 1/09; C08K 7/24; C09D 11/037; H05K 3/00; C09D 11/52; C23C 18/12; H01L 23/498; C23C 18/18; C23C 18/44; H01B 1/24; C09D 11/322

(52) U.S. Cl. CPC C01B 31/0273; H01B 1/24; C08K 7/06; C08K 3/04; H05K 1/09; C08K 7/24; C09D 11/037; C09D 11/322; H05K 3/007; C09D 11/52; C23C 18/122; C23C 18/1245; H01L 23/49877; C23C 18/1889; C23C 18/44

(57) ABSTRACT

The present invention relates to a method of manufacturing coated carbon nanotubes, the method comprising the steps of: functionalizing the carbon nanotubes in a solvent comprising a silane polymer; coating the carbon nanotubes with a SiO₂ layer; depositing metal catalyst particles on the SiO₂ layer of the carbon nanotubes; and performing electroless plating to form an Ag coating on the SiO₂ layer of the carbon nanotubes. The invention also relates Ag-coated CNTs, and to the use of Ag-coated CNTs as interconnects in a flexible electronic film.

### FIELD OF THE INVENTION

The present invention relates to carbon nanotubes and to a method of manufacturing carbon nanotubes. In particular, the present invention relates to a method of manufacturing multi-functionalized carbon nanotubes.

### BACKGROUND OF THE INVENTION

Portable and wearable electronics which are lightweight, highly compact and which can be provided at a low cost can enable a wide variety of new applications, such as paper-like displays, smart clothing, stretchable solar cells, camera eyes and biomedical sensors. The applications for these types of system require flexible interconnection systems that are both highly conductive and sufficiently mechanically robust to have large deformation stability. Moreover, to realize compact, cost-effective electronic devices also demands simple and reliable methods to fabricate such interconnects with arbitrary patterns.

Many materials and technologies have been explored and studied to address the above challenges. For example, conductors made by electroplated sinuous metallic wires embedded within PDMS as electrical circuits have shown a maximum conductivity of 2500 S cm⁻¹ for strains of up to 60% strain. However, its application are limited due to the wave patterned structures and severe failures caused by metal fatigue at large strain. As an alternative to a thin metal layer, composite films have been fabricated through mixing of various conductive fillers, including micro-scaled silver flakes, ionic liquids and CNTs. A very high initial conductivity was achieved in such composite films. However, the films suffered from a significant decrease of conductivity when the tensile strain was above 30%. Moreover, the film had a high production cost and lacked the ability to make fine-patterned structures due to the use of micro-scaled silver flakes.

In view of the above, there is a need for highly conductive and flexible interconnects with superfine structures which can be provided in a simple and low-cost way.

### SUMMARY

In view of above-mentioned and other drawbacks of the prior art, it is an object of the present invention to provide an improved method for manufacturing conductive coated carbon nanotubes suitable for use as a flexible interconnect.

According to a first aspect of the invention, there is provided a method of manufacturing coated carbon nanotubes, the method comprising the steps of: functionalizing the carbon nanotubes in a solvent comprising a silane polymer; coating the carbon nanotubes with a SiO₂ layer; depositing metal catalyst particles on the SiO₂ layer of the carbon nanotubes; and performing electroless plating to form an Ag coating on the SiO₂ layer of the carbon nanotubes.

Electroless plating can also be referred to as chemical or auto-catalytic plating, meaning that plating is performed without the use of electricity.

The present invention is based on the realization that high-performance hybrid nanowires can be prepared using a series of surface modifications on CNT to accomplish complete silver coating and form uniform dispersions whilst protecting the CNTs' original structure and properties.

The multi-functionalized CNT hybrid nanowires manufactured according to the above method, modified with different functional layers for printable, conductive, flexible and stretchable interconnect applications, have been shown to exhibit a superior dispersability in various polar solvents, a high electrical conductivity and good flexibility. The interconnects fabricated from multi-functionalized CNT hybrid nanowires/polydimethysiloxane (PDMS) via direct patterning/printing show a maximum electrical conductivity of 5217 S cm⁻¹ under repeated bending cycles and stabilized at 1000 S cm⁻¹ for strains up to 40%. The observed superior electrical and mechanical performance of the Ag-MWCNT hybrid nanowires indicate the potential use of these materials in wearable flexible displays, stretchable energy generators and capacitors, electronic skins, deformable sensor and actuator applications.

Morphology studies have proved that the Ag-MWCNT bilayer structure can effectively construct electron pathways under large deformation to guarantee stable electrical and mechanical performance due to the intrinsically flexible property of CNTs. Importantly, the Ag-MWCNT hybrid nanowires are able to disperse in various polarity solvents and form stable suspensions which are compatible with many existing patterning/printing techniques. These results facilitate simple and cost-effective approaches to fabricate patterned flexible interconnects with high performance.

According to an embodiment of the invention, the step of functionalizing the carbon nanotubes advantageously comprises dispensing the carbon nanotubes in ethanol comprising (3-Aminopropyl) triethoxysilane (APTES) and polyvinylpyrrolidone (PVP). APTES is a silane polymer and PVP enables a metastable equilibrium of the CNTs in the ethanol solution.

In general, before the metal coating process, surface activation of the CNTs should be carried out to get a homogeneous and stable dispersion. This is commonly achieved through an oxidation pretreatment of CNTs or by surfactant assisted separation processes. However, such treatments lead to severe structural damage to the CNTs or to a poor electrical performance. Here, CNTs were functionalized with a removable polymer layer of (3-Aminopropyl)triethoxysilane (APTES-CNT) to assist its dispersion in polar solvents without any structural damage to the CNTs. A homogeneous CNT ethanol solution was obtained after functionalizing with APTES. Additionally, the APTES-CNT suspension exhibits good stability for a period of at least one month after preparation. No sediments were detected in the ethanol dispersion of APTES-CNTs, which indicates the successful bonding of APTES on the CNT surfaces

In one embodiment of the invention, the step of functionalizing the carbon nanotubes may further comprise the steps of; immersing the CNTs in a solvent comprising an SiO₂ precursor; and providing an alkaline additive in the solvent to form an alkaline solution acting to cross-link the silane polymer such that the silane polymer attaches to the carbon nanotubes. The alkaline additive may advantageously be aqueous ammonia which is added so that the alkaline solution reaches a pH value between 8 and 12.

Furthermore, the cross-linking reaction is preferably performed at a temperature between 20° C. and 50° C.

In one embodiment of the invention, the step of coating the carbon nanotubes with a SiO₂ layer may comprise immersing the carbon nanotubes in a solvent comprising at least one of tetraethyl orthosilicate, diethoxydimethylsilane, vinylotriethoxysilane, and tetramethyl orthosilicate

According the one embodiment of the invention, the method may further comprise sensitizing the SiO₂ coated carbon nanotubes prior to depositing the metal catalyst particles. Sensitizing may for example be performed by immersing the carbon nanotubes in a liquid comprising SnCl₂.2H₂O.

In one embodiment of the invention, the metal catalyst particles may advantageously be Pd particles provided in the form of PdCl₂.

According to one embodiment of the invention, in the step of electroplating to form an Ag coating, Ag may be provided in the form of a solution comprising Ag (Ag(NH3)²⁺) and a reductant.

Furthermore, the reductant may advantageously comprise at least one material selected from the group comprising cobalt sulfate, ferrous chloride, formaldehyde, polyvinylpyrrolidone, glucose, ammonia water, ethylenediamine, ethylenediaminetetraacetic acid and benzotriazole.

According to various embodiments of the invention, the carbon nanotubes may advantageously be multiwalled carbon nanotubes (MWCNTs).

According to a second aspect of the invention, there is provided a method for manufacturing flexible electrical conductors using Ag-coated carbon nanotubes manufactured according to the above described method. The method for manufacturing a flexible conductor comprises the steps of manufacturing coated carbon nanotubes according to any one of the preceding claims; arranging the coated carbon nanotubes on a substrate according to a predefined pattern; immersing the substrate with the carbon nanotube pattern in a solution comprising HF such that the functionalization layer and the SiO₂ layer of the carbon nanotubes is removed; covering a the carbon nanotubes and the surface of the substrate with a PDMS layer; curing the PDMS layer to form a PDMS film; and removing the PDMS film from the substrate such that the predefined pattern of carbon nanotubes are attached to the PDMS film.

Through the removal of the functionalization layer, which as described above may be APTES, and the SiO₂ layer, the remaining hybrid-nanowire structure is a carbon nanotube core surrounded by an Ag shell. Such a hybrid-nanowire structure has proven to have advantageous electrical and mechanical properties when embedded in a PDMS film.

PDMS (polydimethylsiloxane) is a silicone material commonly used as a base material for flexible electronics.

According to one embodiment of the invention, there is provided a flexible electronic conductor comprising: a flexible non-conductive film; a plurality of coated carbon nanotubes at least partially embedded in the flexible film; wherein the carbon nanotube comprises a carbon nanotube core and a silver shell.

In one embodiment of the invention, the step of arranging the coated carbon nanotubes on a substrate according to a predefined pattern may advantageously be performed by spray-printing, ink-jet printing or mask printing.

There is also provided a coated carbon nanotube comprising a first coating layer, arranged on the carbon nanotube, comprising (3-Aminopropyl) triethoxysilane (APTES); a silane layer arranged on said first coating layer; an SiO₂ layer arranged on the silane layer; and an Ag layer arranged on the SiO₂ layer.

Further features of, and advantages with, the present invention will become apparent when studying the appended claims and the following description. The skilled person realize that different features of the present invention may be combined to create embodiments other than those described in the following, without departing from the scope of the present invention.

### BRIEF DESCRIPTION OF THE DRAWINGS

These and other aspects of the present invention will now be described in more detail, with reference to the appended drawings showing an example embodiment of the invention, wherein:

FIGS. 1a-e schematically illustrate a manufacturing method according to an embodiment of the invention;

FIGS. 2a-c schematically illustrate steps of a manufacturing method according to an embodiment of the invention;

FIGS. 3a-d schematically illustrate a manufacturing method according to an embodiment of the invention;

FIGS. 4a-d illustrate the carbon nanotube at different stages in the manufacturing process; and

FIGS. 5a-d illustrate electrical properties of carbon nanotubes manufactured according to an embodiment of the invention.

### DETAILED DESCRIPTION OF EXAMPLE EMBODIMENTS

In the present detailed description, various embodiments of the method according to the present invention are mainly described with reference to Ag-coated multi-walled carbon nanotubes (MWCNTs).

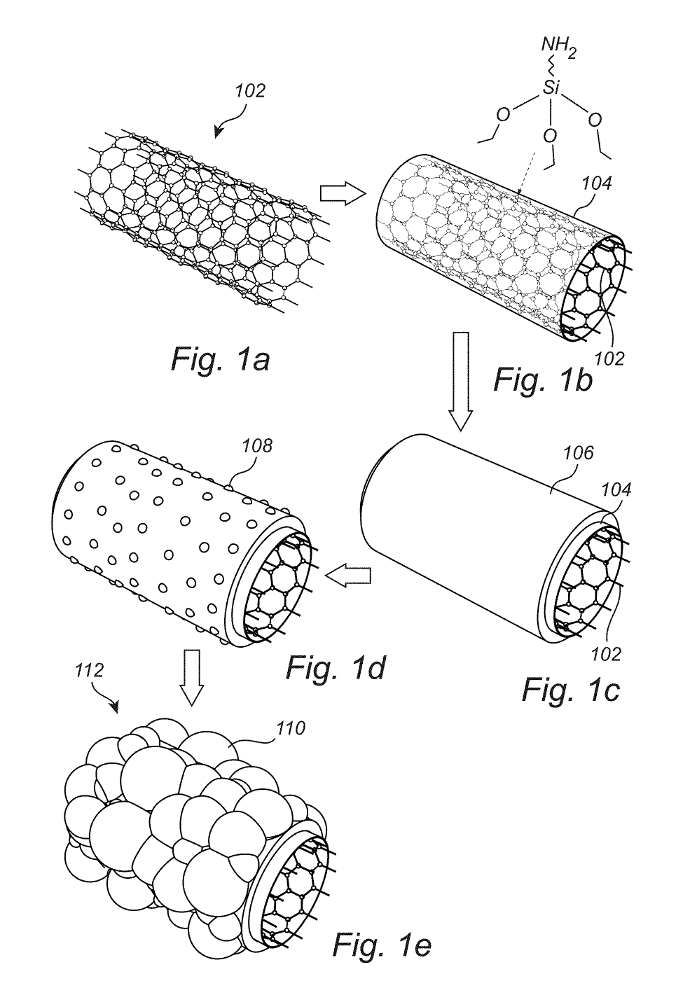

In a first step illustrated in FIG. 1a, MWCNTs 102 with a mean diameter of 15 nm are provided and ultrasonically cleaned in an ethanol solution before use.

MWCNTs are first dispersed into 8 mM APTES ethanol under ultrasonication for 10 min and then vacuum filtrated and rinsed with ethanol. The dried MWCNTs are transferred into an ethanol solution with 2 mg/ml PVP, followed by ultrasonication in a water bath for 30 min to obtain a stable and homogeneous suspension. Immediately afterward, an appropriate amount of aqueous ammonia is added to the above solution to adjust the solution's pH value to approximately 10.

The cross-linking of APTES and its deposition on MWCNTs as illustrated in FIG. 1b is carried out at room temperature in order to form an APTES cover layer 104 on the MWCNT 102. After 4 h, the mixture comprising APTES-coated MWCNTs is filtrated and rinsed with ethanol. The silane modified MWCNTs (APTES-MWCNTs) are subsequently dispersed into a solution with 100 ml ethanol, 2 ml TEOS (tetraethyl orthosilicate) and 5 ml concentrated aqueous ammonia, under ultrasonication.

The coating of silica 106 on MWCNTs illustrated in FIG. 1c is carried out at room temperature and kept in the above solution for 4 h. After reaction, the solution is centrifuged at a moderate speed (3000 rpm) to fully remove free silica particles and to collect the silica coated MWCNTs. The mixture is rinsed thoroughly with ethanol and dried at 60° C. in a vacuum oven. The thickness of the silica coating can be modified by changing the reaction time and the concentration of TEOS. It has been shown that APTES layer does not only assist the dispersion of MWCNTs, but that it also acts as an adhesion layer for the silica coating process so that a uniform SiO₂ layer can be formed. The MWCNTs after silica coating are referred to as SiO₂-MWCNTs.

Following the silica coating, the purified SiO₂-MWCNTs are dispersed into 2 g/L SnCl₂.2H₂O aqueous solution for 20 min under mild stirring condition. Next, the mixture is vacuum filtrated and washed three times with distilled water. The Sn²⁺ sensitized MWCNTs are dispersed into 1 g/L PdCl₂ aqueous solution to deposit palladium metal catalyst particles 108 onto the silica layer 106 as illustrated in FIG. 1d, and the resulting structures are referred to as Pd-MWCNTs.

After the reaction, the Pd-MWCNTs are collected and purified through filtration and washing. Next, the Pd-MWCNTs are kept at 60° C. under vacuum for more than 3 hours to completely remove water. Following that, the Pd-MWCNTs are dispersed in a freshly prepared electroless bath solution (pH=8.5) containing silver complex (4.25 mM Ag(NH₃)²⁺) and a reductant consisting of 2.27×10⁻² M glucose, 2.67 mM tartaric acid and 1.7 M ethanol. To enhance the stability of the plating solution, the reductant solution is boiled for 10 min to thoroughly convert the glucose molecules into an inverted sugar before mixing with the silver complex solution. The reaction is carried out at room temperature with mild stirring. The Ag-plating may in principle be performed at a temperature in the range of 0 to 50° C. to provide the Ag layer 110 as schematically illustrated in FIG. 1e. After 6 hours, the MWCNTs composite was separated, rinsed thoroughly with distilled water and dried at 60° C. in a vacuum oven. The silver coated MWCNTs illustrated in FIG. 1e are referred to as Ag-MWCNTs 112.

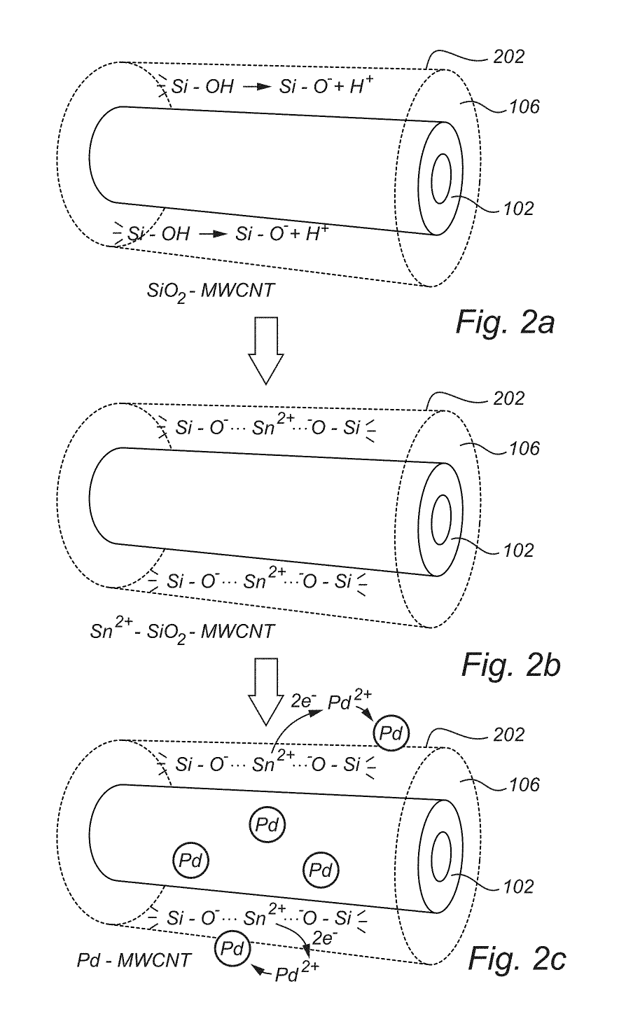

FIGS. 2a-c schematically outlines the reaction mechanism of palladium nanoparticle deposition onto the silica surface 202. FIG. 2a illustrates the SiO₂ coated MWCNT, SiO₂-MWCNT. FIG. 2b illustrates sensitizing SiO₂-MWCNT s by immersing the carbon nanotubes in a SnCl₂.2H₂O aqueous solution. The SiO₂-MWCNTs surfaces exhibit a very strong binding ability with positively charged ions due to the attraction of Si—OH group, and it plays a major role for targeted metal deposition onto the MWCNT surfaces. FIG. 2c illustrates the deposition of palladium nanoparticles on MWCNT (Pd-MWCNTs). Metallic palladium (Pd) nanoparticles are generated through the reduction of Pd²⁺ ions by Sn²⁺ ions which were pre-trapped in the silica layer. A large quantity of palladium nanoparticles with an average particle size of 3 nm are uniformly deposited on the silica surface. The palladium nanoparticles attached at the silica surface act as nucleation sites for the proceeding silver growth on MWCNTs.

The specific materials used in the above process are the following, unless stated otherwise: 3-aminopropyltrietnoxyysilane (APTES, 99%), polyvinylpyrrolidone (PVP, average M=10000 g/mol), tetraethyl orthosilicate (TEOS, 98%,), palladium(II) chloride(99%), tin(II) chloride(98%), silver nitrite(99%), ammonium hydroxide solution(28%), glucose(99.5%), tartaric acid(99.5%), sodium hydroxide(98%) and hydrofluoric acid (48 wt %). Poly(dimethylsiloxane) (PDMS) and curing agents (ELASTOSIL®RT 601A/B).

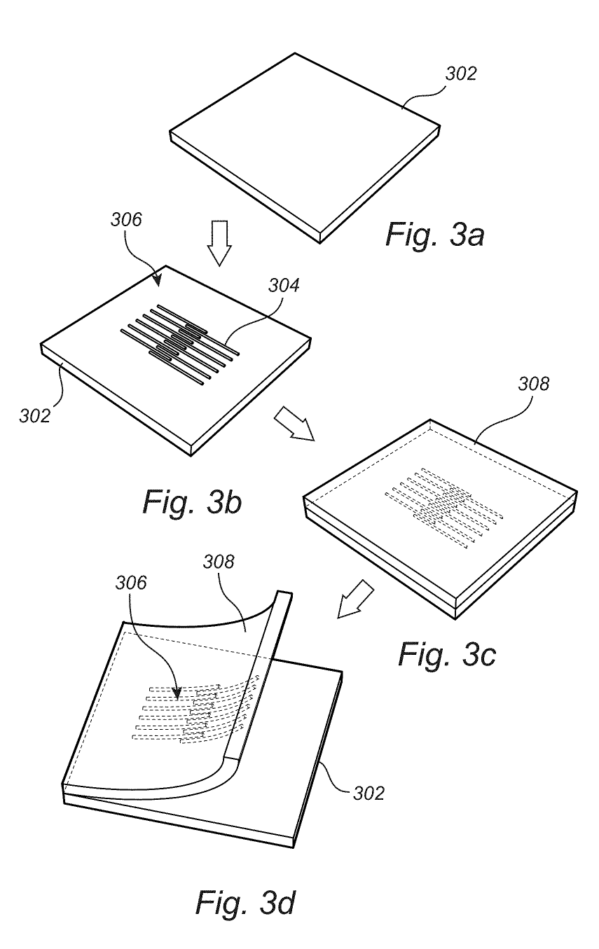

Flexible electrical conductors based on the Ag-MWCNT hybrid nanowires were fabricated through inkjet printing and a mask printing processes as illustrated in FIG. 3a-d.

First, illustrated in FIG. 3a, a substrate 302 is provided which may be a conventional Si substrate, or any other type of suitable substrate. The Ag-MWCNTs 304 are printed onto the substrate, here represented by the pattern 306 shown in FIG. 3b. An Ag-MWCNT hybrid nanowire dispersion can for example be directly spray-printed onto silicon substrates through a shadow mask. Next, the silica and APTES interlayers of the Ag-MWCNTs were completely removed by immersing the patterned circuits in diluted HF solution (10 wt %) for 30 min to provide core-shell Ag coated MWCNTs. After washing and drying, uncured PDMS is dispensed onto the circuits and cured at 80° C. as illustrated in FIG. 3c. In FIG. 3c, the PDMS layer 308 is peeled off from the substrate to expose the Ag-MWCNT based circuits embedded in PDMS.

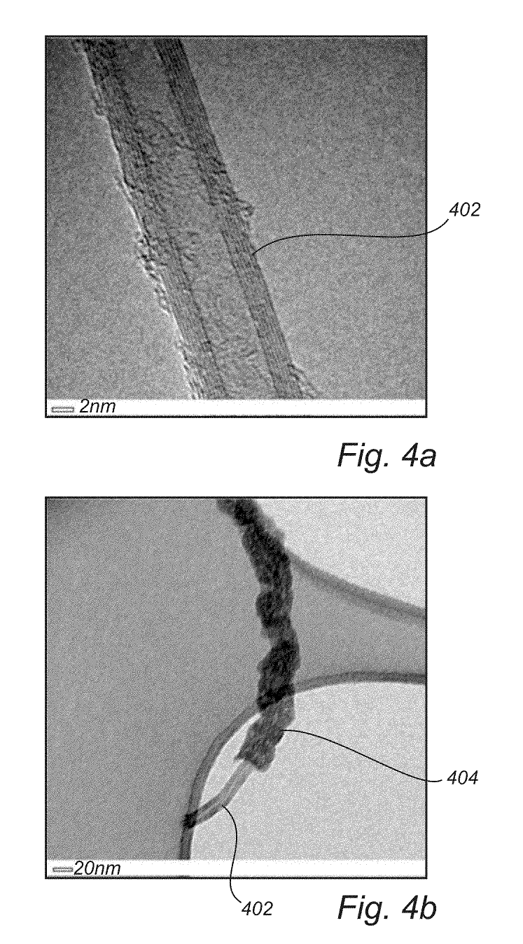

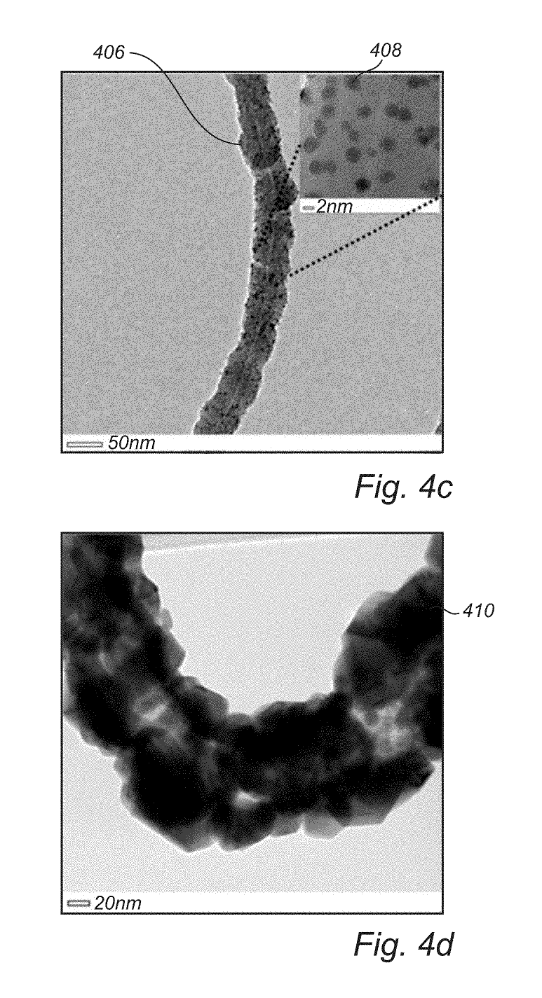

The microstructure of the depositions has been examined at different stages of the process using transmission electron microscopy (TEM) as illustrated in FIGS. 4a-d. FIG. 4a illustrates a pure MWCNT 402 with a diameter of about 15 nm. FIG. 4b illustrates a SiO₂-coated MWCNT. An amorphous silica layer 404 with a thickness about 11.5 nm was deposited. A dense and uniform layer 406 of palladium nuclei 408 with the size of about 3 nm were deposited on silica surface as illustrated in FIG. 4c. No free Pd particles were observed. A continuous silver layer 410 was deposited on the surface of silica as illustrated in FIG. 4d which shows the final multi-functionalized Ag-MWCNT hybrid nanowires. The thickness of the Ag layer is about 50 nm and the Ag particle size is in the range of 20-50 nm.

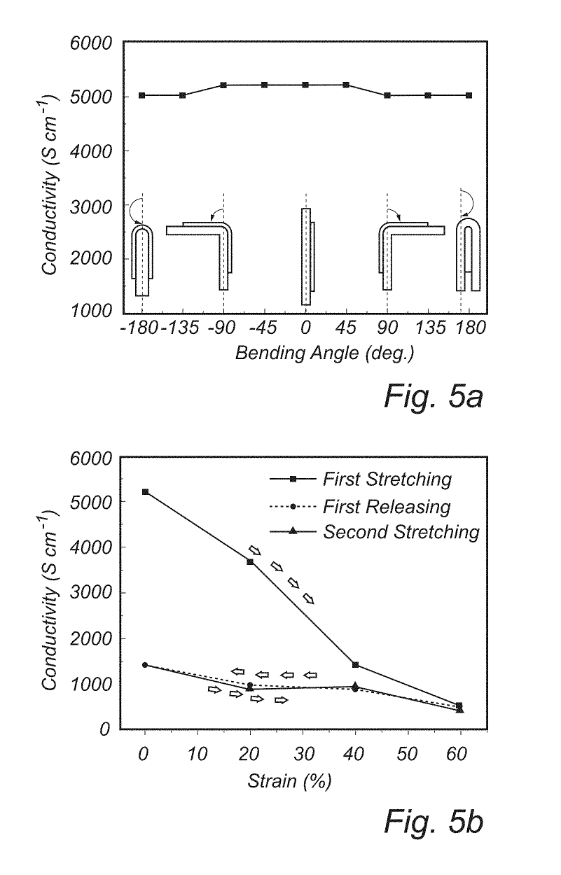

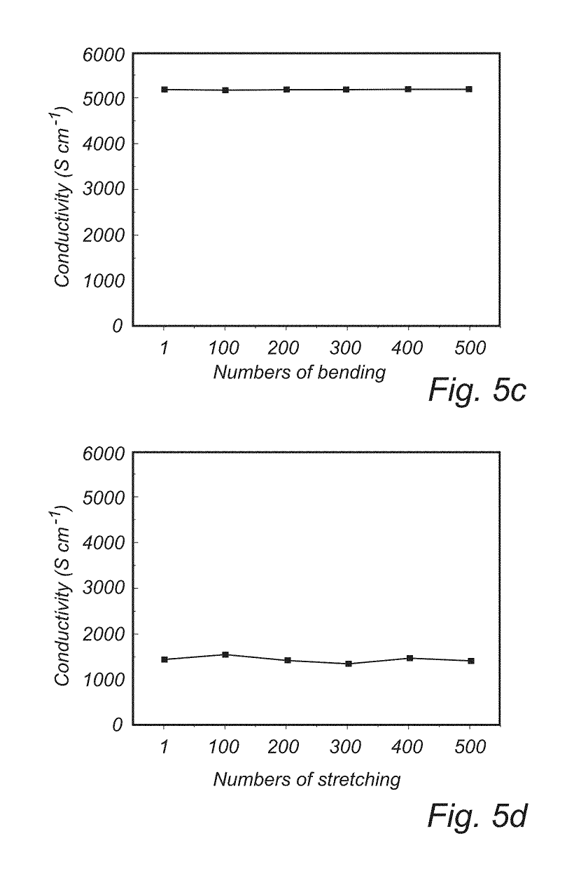

The multi-functionalized CNT-based interconnects have been characterized by means of electrical conductivity measurements under and after stretching and bending. FIG. 5a illustrates the electrical conductivity of multi-functionalized interconnects as a function of different bending angles. Only a very small variation of conductivity, less than 3.8%, was observed when the interconnect was bent up to 180°. FIG. 5b illustrates interconnect conductivity as a function of the number of bending cycles. The conductivity showed little change after 500 cycles of bending-unbending, which demonstrates the highly stable electrical and mechanical performance of the Multi-functionalized CNT-based interconnects. FIG. 5c illustrates the conductivity of interconnects as a function of applied strain. It can be seen that the conductivity decreased from 5217 S cm-1 to 520 S cm⁻¹ at 60% strain during the first stretching cycle. After releasing the strain, conductivity was partially recovered and stabilized to 1429 S cm⁻¹. Further stretching showed a stable conductivity value (1000 S cm⁻¹) within 40% strains. FIG. 5d illustrates conductivity under repeated stretch and release cycles. The multi-functionalized CNT-based interconnects showed a highly stable conductivity with less than 8% variation after 500 repeated strain-cycles.

Accordingly, the flexible and stretchable interconnects based on the Ag-MWCNT hybrid nanowires and PDMS demonstrate excellent and stable electrical performance under repeated bending tests and good electrical restorability under stretching cycles. A morphology study has shown that the Ag-MWCNT bilayer structure can effectively construct electron pathways under large deformation to guarantee stable electrical and mechanical performance. Importantly, the Ag-MWCNT hybrid nanowires are able to disperse in various polarity solvents and form stable suspensions which are compatible with many existing patterning/printing techniques. These results facilitate simple and cost-effective approaches to fabricate superfine patterned flexible interconnects with high performance.

Even though the invention has been described with reference to specific exemplifying embodiments thereof, many different alterations, modifications and the like will become apparent for those skilled in the art. Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

1. Method of manufacturing coated carbon nanotubes, the method comprising the steps of:
functionalizing said carbon nanotubes in a solvent comprising a silane polymer;
coating said carbon nanotubes with a SiO₂ layer;
depositing metal catalyst particles on said SiO₂ layer of said carbon nanotubes; and
performing electroless plating to form an Ag coating on said SiO₂ layer of said carbon nanotubes.

2. The method according to claim 1, wherein said step of functionalizing said carbon nanotubes comprises dispensing said carbon nanotubes in ethanol comprising (3-Aminopropyl) triethoxysilane (APTES) and polyvinylpyrrolidone (PVP).

3. The method according to claim 1, wherein said step of functionalizing said carbon nanotubes further comprises the steps of;
immersing said CNTs in a solvent comprising an SiO₂ precursor; and
providing an alkaline additive in said solvent to form an alkaline solution acting to cross-link said silane polymer such that said silane polymer attaches to said carbon nanotubes.

4. The method according to claim 3, wherein said alkaline additive is aqueous ammonia.

5. The method according to claim 3, wherein said alkaline additive is added such that said alkaline solution reaches a pH value between 8 and 12.

6. The method according to claim 3, wherein said cross-linking is performed at a temperature between 20° C. and 50° C.

7. The method according to claim 1, wherein said step of coating said carbon nanotubes with a SiO₂ layer comprises immersing said carbon nanotubes in a solvent comprising at least one of tetraethyl orthosilicate, diethoxydimethylsilane, vinylotriethoxysilane, and tetramethyl orthosilicate

8. The method according to claim 1, further comprising sensitizing said SiO₂ coated carbon nanotubes prior to depositing said metal catalyst particles.

9. The method according to claim 8, wherein sensitizing is performed by immersing said carbon nanotubes in a liquid comprising SnCl₂.2H₂O.

10. The method according to claim 1, wherein said metal catalyst particles are Pd particles.

11. The method according to claim 10, wherein said Pd particles are provided in the form of PdCl₂.

12. The method according to claim 1, wherein electroless plating is performed by immersing said carbon nanotubes in a solution comprising Ag (Ag(NH₃)²⁺) and a reductant.

13. The method according to claim 12, wherein said reductant comprises at least one material selected from the group comprising cobalt sulfate, ferrous chloride, formaldehyde, polyvinylpyrrolidone, glucose, ammonia water, ethylenediamine, ethylenediaminetetraacetic acid and benzotriazole.

14. The method according to claim 1, wherein said carbon nanotubes are multiwalled carbon nanotubes.

15. Method for manufacturing flexible electrical conductors comprising the steps of:
manufacturing coated carbon nanotubes according to claim 1;
arranging said coated carbon nanotubes on a substrate according to a predefined pattern;
immersing said substrate comprising said carbon nanotubes in a solution comprising HF such that said functionalization layer and said SiO₂ layer of said carbon nanotubes is removed;
covering a said carbon nanotubes and said surface of said substrate with a PDMS layer;
curing said PDMS layer to form a PDMS film; and
removing said PDMS film from said substrate such that said predefined pattern of carbon nanotubes are attached to said PDMS film.

16. The method according to claim 15, wherein said step of arranging said coated carbon nanotubes on a substrate according to a predefined pattern is performed by spray-printing, ink-jet printing or mask printing.

17. A coated carbon nanotube comprising:
a first coating layer, arranged on said carbon nanotube, comprising (3-Aminopropyl)triethoxysilane (APTES);
a silane layer arranged on said first coating layer;
an SiO₂ layer arranged on said silane layer; and
an Ag layer arranged on said SiO₂ layer.

18. A flexible electronic conductor comprising:
a flexible non-conductive film;
a plurality of coated carbon nanotubes according to claim 17 at least partially embedded in said flexible film; wherein said carbon nanotubes comprises a carbon nanotube core and a silver shell.

19. A flexible electrical conductor manufactured according to the method of claim 15.
